(19) United States
(12) Patent Application Publication
(10) Pub. No.: US 2011/0124139 A1
(43) Pub. Date: May 26, 2011

(54) METHOD FOR MANUFACTURING FREE-STANDING SUBSTRATE AND FREE-STANDING LIGHT-EMITTING DEVICE

(76) Inventor: Chun-Yen CHANG, Baoshan Township (TW)

(21) Appl. No.: 12/788,518

(22) Filed: May 27, 2010

(30) Foreign Application Priority Data
Nov. 24, 2009 (TW) 098139899

(51) Int. Cl. H01L 33/02; H01L 21/02

(52) U.S. Cl. 438/40; 438/478; 438/745; 257/E21.002; 257/E33.005

(57) ABSTRACT

The present invention provides a method for manufacturing a free-standing substrate, comprising: growing a first layer having a sacrificial layer on a growth substrate; patterning the first layer into a patterned first layer having a structure of a plurality of protrusions; growing a second layer on the patterned first layer having a structure of a plurality of protrusions by epitaxial lateral overgrowth; and separating the second layer from the growth substrate by etching away the sacrificial layer, wherein the separated second layer functions as a free-standing substrate for epitaxy. Also, the present invention provides a method for manufacturing a free-standing light-emitting device, comprising: growing a first layer having a sacrificial layer on a growth substrate; patterning the first layer into a patterned first layer having a structure of a plurality of protrusions; growing a second layer on the patterned first layer having a structure of a plurality of protrusions by epitaxy growth; forming a reflecting layer on the second layer; forming a conductive substrate on the reflecting layer; and separating the second layer, the reflecting layer, and the conductive substrate from the growth substrate by etching away the sacrificial layer, so as to form a free-standing light-emitting device.

### BACKGROUND OF THE INVENITON

1. Field of the Invention

The present invention relates to a method for manufacturing a free-standing substrate and a free-standing light-emitting device. In particular, the present invention relates to a method for manufacturing a free-standing substrate for use of subsequent epitaxy or a free-standing vertical light-emitting device by etching a sacrificial layer patterned into a plurality of protrusions to separate a growth substrate.

2. Description of the Related Art

A light-emitting diode (LED) is a semiconductor material, in which a p-type semiconductor, an n-type semiconductor, and a light-emitting layer are epitaxially grown on a substrate. For group III-V compound semiconductors, sapphire is mainly used as a growth substrate. However, since the sapphire is non-conductive and electrodes cannot be formed thereon, in the case of the formation of a vertical LED, a sapphire substrate is mostly and finally removed. Moreover, with the brightness of LED die enhanced, the power consumption of a single LED is increased from several microwatts to 1 watt, 3 watts or even more than 5 watts. In order to prevent heat accumulation, heat must be rapidly sent to outside. Therefore, the sapphire substrate with poor heat dissipation is removed to have metal with better thermal conductivity attached so as to further satisfy the requirement of heat dissipation of high power LEDs and resolve the current crowding problem.

Document 1 (U.S. Pat. No. 6,071,795) discloses a method of separating a thin film from a growth substrate. Referring to FIG. 1, the method comprises: growing a film 102 of a first composition on a first side of a first substrate 104 of a second composition, wherein the film comprises a III-V nitride compound and the first substrate comprises sapphire; bonding a second substrate 110 to a side of the film opposite the first substrate; irradiating the film from an irradiation side of the first substrate with light 116 having a wavelength that is strongly absorbed by the film, to form an interfacial layer 118 between the film and the first substrate; and detaching the second substrate together with portions of the film attached thereto from the first substrate.

As can be known from its specification and drawing, in this method, the bonding between the second substrate 110 and the film 102 is achieved through a bonding layer 108. Thus, there is a non-conductive bonding layer between the second substrate 110 (for example, a silicon substrate) and the film 102 (for example, a GaN film), so it cannot be a basic structure for a vertical light-emitting device. Furthermore, an inappropriate coating or material selection will affect the adhesive effect of the bonding layer 108, and even cause defects generated in the GaN film.

Document 2 (U.S. Pat. No. 6,740,604 B2) discloses a method of separating two layers of materials from one another and substantially completely preserving each of the two layers of materials. The method comprises: providing two layers of materials having an interface boundary between the two layers, one of the two layers of materials being a substrate and the other of the two layers of materials being a semiconductor body having a layer of group III nitride material or a layer system of group III nitride materials; irradiating the interface boundary between the two layers or a region in vicinity of the interface boundary with electromagnetic radiation through the substrate; and absorbing the electromagnetic radiation at the interface or in the vicinities of the interface and initiating decomposition of the layer of group III nitride material or the layer system of group III nitride materials and the formation of nitrogen gas.

This method needs a high power laser to separate the two layers of materials. When the laser focuses on the plane of layer and scans, the overlap or gap problem easily arises to cause an energy input on the scan interface overlapped or insufficient, resulting yield down or fragmentation. Also, since the transient temperature on the separation interface reaches over 600° C., it is easy to cause damages to the device. Moreover, due to the laser being expensive and having limited life time, it is difficult to reduce unit production cost.

Document 3 (U.S. Pat. No. 6,746,889) discloses a method of manufacturing an optoelectronic device, comprising: (a) providing a substrate having first and second major surfaces; (b) growing epitaxial layers on the first major surface of the substrate, the epitaxial layers including a first region of a first conductivity type, a second region of a second conductivity type, and a light-emitting p-n junction between the first region and the second region; (c) forming separations of substantially equal depth through the epitaxial layers to about the first major surface of the substrate to provide a structure including a plurality of individual dies on the first major surface of the substrate; (d) mounting the structure to a submount at the first region of the individual dies to expose the second major surface of the substrate; and (e) removing the substrate from the structure, wherein the width of the separations is 20 μm˜30 μm.

As can be known from the specification of document 3, the separations are formed by cutting, and the substrate is removed by laser, abrasion or etching. However, in this method, the formed structure is attached to a fixture when cutting the epitaxial layers, so mutual pushing easily arises due to an external force action, resulting in die crack.

Document 4 (U.S. Pat. No. 6,617,261) discloses a method for making a gallium nitride substrate for a nitride based semiconductor structure, comprising the steps of: depositing a gallium nitride layer on a sapphire substrate; etching at least one trench through the gallium nitride layer to the sapphire substrate, the at least one trench dividing the gallium nitride layer into a plurality of gallium nitride substrates; attaching a support substrate to a side of the plurality of gallium nitride substrates opposite the sapphire substrate; removing the sapphire substrate from the plurality of gallium nitride substrates; and removing the support substrate from the plurality of gallium nitride substrates.

As can be known from line 54, column 8 to line 5, column 9 of its specification, the method uses the irradiation of a laser beam from the sapphire substrate side to decompose the GaN layer at the GaN layer/sapphire substrate interface into Ga metal and N₂. Therefore, the residual Ga metal on the surface of the GaN substrate must be removed by a hydrochloric acid (HCl) and water solution dip in order to perform a subsequent epitaxy process.

Document 5 (WO 2007-107757 A2 and TW 200801257) discloses a method of producing single-crystal compound semiconductor material. Referring to FIG. 2, the method comprises: providing a substrate 10 having a compound semiconductor nanostructure 12 (i.e., nano-columns, nano-rods) grown onto it to provide an epitaxial-initiating growth surface; growing a compound semiconductor material 15 onto the nanostructure 12 using epitaxial lateral overgrowth (referred to as ELOG); and separating the grown compound semiconductor material 15 from the substrate 10, wherein the nanostructure 12 is made of a material selected from the group consisting of GaN, AlN, InN, ZnO, SiC, Si, and alloys thereof, and the separation is performed by wet etching.

In the method disclosed by document 5, the nanostructure 12 functioning as a separation means is a single semiconductor material, so this method cannot perform a selective etching by disposing a sacrificial layer. Moreover, in the case of growing the nanostructure 12 by epitaxy, it is difficult to control uniformity. Therefore, it is difficult to control quality and yield. Also, since the individual nano-columns are grown independently, there is a problem that the lattice orientations thereof are in different phases.

Document 6 (Jun-Seok Ha et al., IEEE PHOTONICS TECHNOLOGY LETTERS, VOL. 20, NO. 3, Feb. 1, 2008) discloses a method of fabricating vertical light-emitting diodes using chemical lift-off process (referred to as CLO). The method comprises: sequentially forming a CrN layer, an n-type GaN layer, an active layer, a p-type GaN layer, a p-type contact, and a metal substrate on a sapphire substrate; removing the sapphire substrate and exposing the surface of the n-type GaN layer by etching the CrN layer; and forming an n-type contact on the exposed surface of the n-type GaN layer.

In the method disclosed by document 6, the CrN layer is used as a buffer layer for a group III nitride layer. However, as compared to a vertical LED manufactured by a laser-induced lift-off (referred to as LLO), the method can sacrifice the quality of the GaN material and reduce light emitting efficiency.

Document 7 (M. K. Kelly et al., Jpn. J. Appl. Phys. 38, L217-L219 (1999)) discloses a method of manufacturing a large free-standing GaN substrate by hydride vapor phase epitaxy (referred to as HVPE) and laser-induced lift-off, in which a pulsed laser is used to thermally decompose a thin layer of GaN at a thin film of GaN-sapphire substrate interface, and then, scanned pulses are employed and the liftoff was performed at elevated temperature (>600° C.).

Also, document 8 (C. R. Miskys et al., Phys. Stat. Sol. (c) 6, 1627-1650 (2003)) discloses a method of separating a sapphire substrate and a GaN layer by laser-induced lift-off, in which high intensity laser pulses enter a sample via a sapphires substrate and thermally decompose a thin GaN layer at a substrate interface, and the method is characterized in that the shock waves resulting from the explosive production of nitrogen gas during each laser pulse are damped by placing the GaN sample into sapphire powder or covering the GaN film with a silicone elastomer.

The laser-induced lift-off method disclosed in documents 7 and 8 has the disadvantages as described in document 2.

Document 9 (Y. Oshima et al., Jpn. J. Appl. Phys. 42, L1 (2003)) discloses a method of preparing a free-standing GaN wafer by HVPE and void-assisted separation (referred to as VAS). A thick GaN layer is formed on a GaN template having a thin TiN film thereon by HVPE. After cooling, the thick GaN layer is easily separated from the template so as to manufacture a free-standing GaN wafer having a mirror surface, with the aid of voids formed around the TiN film.

In the method disclosed by document 9, the process of growing TiN is more complicated and belongs to heteroepitaxy, as compared to the subsequent process of growing GaN.

Document 10 (H. J. Lee et al., Phys. Stat. Sol (c) 4, 2268-2271 (2007)) discloses a method of manufacturing a free-standing GaN layer with a GaN nanorod buffer layer. A GaN buffer layer with a nanorod structure is grown on a C-sapphire substrate at a temperature below 650° C. by HYPE. Then, the temperature is raised up to 1040° C., and a thick GaN layer is grown by epitaxial lateral overgrown. The thick GaN film is self-separated during cooling down by thermal stress caused by the difference of thermal expansion coefficient (TEC) between GaN and sapphire. Moreover, since the nanorod buffer layer consists of nano-rods and voids, it is mechanically weaker than planar GaN layers and contributes to the self-separation of the thick GaN film.

However, in the method disclosed by document 10, the nano-rods are grown directly by HYPE, so process parameters, such as V/III ratio, growth temperature, growth time, etc., must be adjusted to control the sizes of the nano-rods, and the formation of the nano-rods is sensitive to growth temperature (referring to lines 2224, page 2269 in document 10). Therefore, the sizes of the nano-rods are quite inconsistent and have poor repeatability. As a result, it is difficult to obtain stable process conditions and separation effect and it is not conductive to mass production.

Document 11 (Kazuhide Kusakabe et al., Journal of Crystal Growth 237-239 (2002) 988-992) discloses a method of growing a GaN layer on GaN nano-columns by a RF-molecular beam epitaxy. As compared to document 10, the same point is that GaN is grown into the shape of nano-columns directly on a sapphire substrate; and the different point in the method disclosed by document 11 is that before growing the nano-columns, an AlN nucleation layer with island features on its surface morphology is first deposited on a sapphire substrate, and the growth of the subsequent GaN nano-columns is initiated using the AlN nuclei. Therefore, like the method disclosed in document 10, this method is not conductive to mass production.

### SUMMARY OF THE INVENTION

In view of the above problems, the present inventor studies diligently and proposes a method for separating a growth substrate and a light-emitting device, instead of conventional methods, for example, laser lift-off, CrN chemical lift-off, nano-columns lift-off, void-assisted separation, etc.

A first aspect of the present invention is a method for manufacturing a free-standing substrate, comprising: growing a first layer having a sacrificial layer on a growth substrate; patterning the first layer into a patterned first layer having a structure of a plurality of protrusions; growing a second layer on the patterned first layer having a structure of a plurality of protrusions by epitaxial lateral overgrowth; and separating the second layer from the growth substrate by etching away the sacrificial layer, the separated second layer functioning as a free-standing substrate for epitaxy.

A second aspect of the present invention is according to the first aspect, wherein the growth substrate is made of one selected from the group consisting of sapphire, silicon, silicon carbide, diamond, metal, LiAlO₂ (lithium aluminate, LAO), LiGaO₂ (lithium gallate, LGO), ZnO, GaAs, GaP, metal oxide, compound semiconductor, glass, quartz, and their composite materials.

A third aspect of the present invention is according to the first aspect, wherein the first layer consists of a first group III nitride layer, a nitride sacrificial layer, and a second group III nitride layer, wherein the nitride sacrificial layer is between the first group III nitride layer and the second group III nitride layer, the first layer is 1 nm or more and 10 μm or less in thickness, and the nitride sacrificial layer is 1 nm or more and 10 μm or less in thickness. The first layer may consists of a plurality of sub-layers with the following expression: GaN/(AlₓGa₁₋ₓN/GaN)ₖ, 0<x≦1, k is an integer of 1 or more.

A fourth aspect of the present invention is according to the first aspect, wherein the first layer consists of a group III nitride layer and a nitride sacrificial layer, wherein the nitride sacrificial layer is above or below the group III nitride layer, the first layer is 1 nm or more and 10 μm or less in thickness, and the nitride sacrificial layer is 1 nm or more and 10 μm or less in thickness.

A fifth aspect of the present invention is according to the first aspect, wherein the first layer consists of a nitride sacrificial layer, and the first layer is 1 nm or more and 10 μm or less in thickness.

A sixth aspect of the present invention is according to the third to fifth aspects, wherein the nitride sacrificial layer is made of one selected from the group consisting of SiO₂, Si₃N₄, CrN, ZnO, TiN, Al₂O₃, (InₓAl_{y}Ga_{1-x-y}N), wherein 0≦x≦1, 0≦y≦1, x+y≦1, and combinations thereof.

A seventh aspect of the present invention is according to the third to fifth aspects, wherein the nitride sacrificial layer is a superlattice structure that comprises a plurality of alternating (InₓAl_{y}Ga_{1-x-y}N) sub-layer and (InₘAlₙGa₁₋ₘ₋ₙN) sub-layer, wherein 0≦m, n, x, y≦1, x+y≦1, m+n≦1, and m≠x, n≠y, 1-x-y≠1-m-n.

A eighth aspect of the present invention is according to the first aspect, wherein the step of patterning the first layer is to form a patterned mask layer on the first layer by photolithography process, lift-off process or imprint process and etch the first layer into a structure having a plurality of protrusions by using the patterned mask layer as an etching mask.

A ninth aspect of the present invention is according to the eighth aspect, wherein the mask layer is made of metal or polymeric material.

A tenth aspect of the present invention is according to the first aspect, wherein the step of patterning the first layer is to distribute a plurality of masks on the first layer by spray, thereby etching the first layer into a structure having a plurality of protrusions.

A eleventh aspect of the present invention is according to the first aspect, wherein the step of patterning the first layer is to form a plurality of individually separated masks on the first layer by self-assembly, thereby etching the first layer into a structure having a plurality of protrusions.

A twelfth aspect of the present invention is according to the first aspect, wherein as shown in FIGS. 3(a)˜(c), a plurality of columns 22 on a growth substrate 20 present an island-like distribution in top view, that is, they are in a pillar form.

A thirteenth aspect of the present invention is according to the first aspect, wherein as shown in FIG. 3(d), a plurality of columns 22 on a growth substrate 20 present a stripe-like distribution in top view, that is, they are in an elongated form.

A fourteenth aspect of the present invention is according to the twelfth or thirteenth aspect, wherein referring to FIG. 3(e), a bottom width w of the protrusion is 10 nm≦w≦1 mm, a top width v of the column is 10 nm≦v≦1 mm, a height h of the protrusion is 30 nm≦h≦1 mm, a distance d between two adjacent protrusions is 10 nm≦d≦10 μm.

A fifth aspect of the present invention is according to the first aspect, wherein the second layer is made of nitride.

A sixteenth aspect of the present invention is according to the first aspect, wherein the etching is wet etching using an etchant.

A seventeenth aspect of the present invention is according to the sixteenth aspect, wherein the used etchant is one selected from the group consisting of AZ400K (a mixture solution of H₃BO₃ and KOH as main components, manufactured by Clariant Company), KOH, H₃BO₃, H₂SO₄, H₃PO₄, HF, HNO₃, H₂O₂, HCl, buffered oxide etchant, and combinations thereof.

A eighteenth aspect of the present invention is a method for manufacturing a free-standing light-emitting device, comprising: growing a first layer having a sacrificial layer on a growth substrate; patterning the first layer into a patterned first layer having a structure of a plurality of protrusions; growing a second layer on the patterned first layer having a structure of a plurality of protrusions by epitaxy growth; forming a reflecting layer on the second layer; forming a conductive substrate on the reflecting layer; and separating the second layer, the reflecting layer, and the conductive substrate from the growth substrate by etching away the sacrificial layer, so as to form a free-standing light-emitting device.

A nineteenth aspect of the present invention is according to the eighteenth aspect, wherein the growth substrate is made of one selected from the group consisting of sapphire, silicon, silicon carbide, diamond, metal, LiAlO₂(lithium aluminate, LAO), LiGaO₂ (lithium gallate, LGO), ZnO, GaAs, GaP, metal oxide, compound semiconductor, glass, quartz, and their composite materials.

A twentieth aspect of the present invention is according to the eighteenth aspect, wherein the first layer consists of a first group III nitride layer, a nitride sacrificial layer, and a second group III nitride layer, wherein the nitride sacrificial layer is between the first group III nitride layer and the second group III nitride layer, the first layer is 1 nm or more and 10 μm or less in thickness, and the nitride sacrificial layer is 1 nm or more and 10 μm or less in thickness. The first layer may consists of a plurality of sub-layers with the following expression: GaN/(AlₓGa₁₋ₓN/GAN)ₖ, 0<x≦1, k is an integer of 1 or more.

A twenty-first aspect of the present invention is according to the eighteenth aspect, wherein the first layer consists of a group III nitride layer and a nitride sacrificial layer, wherein the nitride sacrificial layer is above or below the group III nitride layer, the first layer is 1 nm or more and 10 μm or less in thickness, and the nitride sacrificial layer is 1 nm or more and 10 μm or less in thickness.

A twenty-second aspect of the present invention is according to the eighteenth aspect, wherein the first layer consists of a nitride sacrificial layer, and the first layer is 1 nm or more and 10 μm or less in thickness.

A twenty-third aspect of the present invention is according to the twentieth aspect, wherein the nitride sacrificial layer is made of one selected from the group consisting of SiO₂, Si₃N₄, CrN, ZnO, TiN, Al₂O₃, (InₓAl_{y}Ga_{1-x-y}N), wherein 0≦x≦1, 0.5≦y≦1, x+y≦1, and combinations thereof.

A twenty-fourth aspect of the present invention is according to the twentieth to twenty-second aspects, wherein the nitride sacrificial layer is a superlattice structure that comprises a plurality of alternating (InₓAl_{y}Ga_{1-x-y}N) sub-layer and (InₘAlₙGa₁₋ₘ₋ₙN) sub-layer, wherein 0≦m, n, x, y≦1, x+y≦1, m+n≦1, and m≠x, n≠y, 1-x-y≠1-m-n.

A twenty-fifth aspect of the present invention is according to the eighteenth aspect, wherein the step of patterning the first layer is to form a patterned mask layer on the first layer by photolithography process, lift-off process or imprint process and etch the first layer into a structure having a plurality of protrusions by using the patterned mask layer as an etching mask.

A twenty-sixth aspect of the present invention is according to the twenty-fifth aspect, wherein the mask layer is made of metal or polymeric material.

A twenty-seventh aspect of the present invention is according to the eighteenth aspect, wherein the step of patterning the first layer is to distribute a plurality of masks on the first layer by spray, thereby etching the first layer into a structure having a plurality of protrusions.

A twenty-eighth aspect of the present invention is according to the eighteenth aspect, wherein the step of patterning the first layer is to form a plurality of individually separated masks on the first layer by self-assembly, thereby etching the first layer into a structure having a plurality of protrusions.

A twenty-ninth aspect of the present invention is according to the eighteenth aspect, wherein the plurality of protrusions on the growth substrate present an island-like distribution in top view, that is, they are in a pillar form.

A thirtieth aspect of the present invention is according to the eighteenth aspect, wherein the plurality of protrusions on the growth substrate present a stripe-like distribution in top view, that is, they are in an elongated form.

A thirty-first aspect of the present invention is according to the twenty-ninth or thirtieth aspect, wherein a bottom width w of the protrusion is 10 nm≦w≦1 mm, a top width v of the protrusion is 10 nm≦v≦1 mm, a height h of the protrusion is 30 nm≦h≦1 mm, the distance d between two adjacent protrusions is 10 nm≦d≦10 μm.

A thirty-second aspect of the present invention is according to the eighteen aspect, wherein the second layer comprises an n-type group III nitride layer, formed on the patterned first layer; a multiple quantum-well group III nitride layer, formed on the n-type group III nitride layer; and a p-type group III nitride layer, formed on the multiple quantum-well group III nitride layer.

A thirty-third aspect of the present invention is according to the eighteen aspect, wherein the etching is wet etching using an etchant.

A thirty-fourth aspect of the present invention is according to the eighteen aspect, wherein the used etchant is one selected from the group consisting of AZ400K (a mixture solution of H₃BO₃ and KOH as main components, manufactured by Clariant Company), KOH, H₃BO₃, H₂SO₄, H₃PO₄, HF, HNO₃, H₂O₂, HCl, buffered oxide etchant, and combinations thereof.

A thirty-fifth aspect of the present invention is according to the eighteen aspect, wherein the reflecting layer is made of one selected from the group consisting of Ag, Al, Ni, Au, Pt, Ti, Cr, Pd, and their alloys.

A thirty-sixth aspect of the present invention is according to the eighteen aspect, wherein the conductive substrate is made of at least one selected from the group consisting of Cu, Si, Ni, Sn, Mo, AlN, SiC, SiCN, W, WC, CuW, TiW, TiC, GaN, diamond, metal, metal oxide, compound semiconductor, and their composite materials.

### The Effects of the Present Invention

As compared to the laser lift-off that uses laser to generate a high temperature (>600° C.) so as to decompose the interface between a growth substrate and a light-emitting layer, the present invention uses a chemical etching process with an operating temperature below 80° C. for separation, thereby avoiding that the high-temperature separation process causes damages to the resulting light-emitting device.

Also, as compared to the lift-off method disclosed in documents 5, 10, and 11, which grows GaN into a nanorod structure directly, the present invention does not have the following disadvantages: the nano-rods tend to have the lattice orientations in different phases due to being grown independently, the directly grown nano-rods have poor repeatability, and it is not conductive to mass production.

Furthermore, as compared to the method disclosed in document 6, which initiates etching from outside of the CrN buffer layer, the present invention forms the sacrificial layer into rod shape, so it is advantageous to allow the etchant flowing throughout the opened internal part of the sacrificial layer so as to have uniform etching.

Moreover, as compared to the void-assisted separation method disclosed in document 9, which uses voids formed by TiN, and in which the processes for growing TiN and subsequently growing GaN belong to heteroepitaxy, the nanorod structure of the present invention, GaN/AlN/GaN, belongs to homoepitaxy with low technical complexity and it is conductive to mass production.

Also, the present invention adopts lateral overgrowth to grow the GaN layer on the nano-rods. Therefore, as compared to the film formation on a planar underlying layer, it can further reduce residual strains or stresses caused by the film formation, decrease defect density, and improve epitaxial quality. Furthermore, in the present invention, when the chemical etching is used to separate the growth substrate, the exposed surface of the light-emitting layer is simultaneously roughened. Moreover, after the AlN sacrificial layer is laterally etched away, GaN (N-face and Ga-face) having different polarities are generated and an upward etching phenomenon takes place to roughen the surface thereof, so as to achieve the double rough effect and increase the light extraction efficiency of the light-emitting device.

As described above, according to the method of the present invention, a free-standing vertical light-emitting diode can be stably manufactured by a simple process.

### BRIEF DESCRIPTION OF THE DRAWINGS

FIG. 1 shows a prior art which separates a growth substrate by laser irradiation.

FIG. 2 shows a prior art which separates a growth substrate by nanostructure.

FIG. 3(a)˜(c) are plan views showing that the protrusions of the present invention on a growth substrate present a island-like distribution; (d) is a plan view showing that the protrusions of the present invention on a growth substrate present a stripe-like distribution; (e) is a cross-sectional view of the protrusions together with the growth substrate of the present invention.

FIG. 4 is a flow chart explaining an embodiment of manufacturing a free-standing substrate of the present invention.

FIGS. 5 to 11 are cross-sectional views showing a method for manufacturing a free-standing substrate according to an embodiment of the present invention.

FIGS. 12 to 18 are cross-sectional views showing a method for manufacturing a free-standing substrate according to another embodiment of the present invention.

FIG. 19 is a flow chart explaining an embodiment of manufacturing a free-standing light-emitting device of the present invention.

FIGS. 20 to 27 are cross-sectional views showing a method for manufacturing a free-standing light-emitting device according to another embodiment of the present invention.

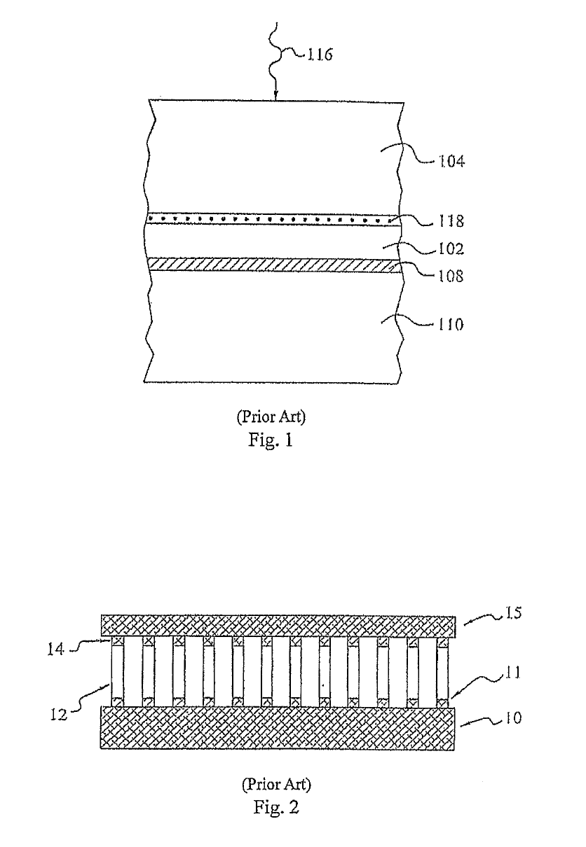

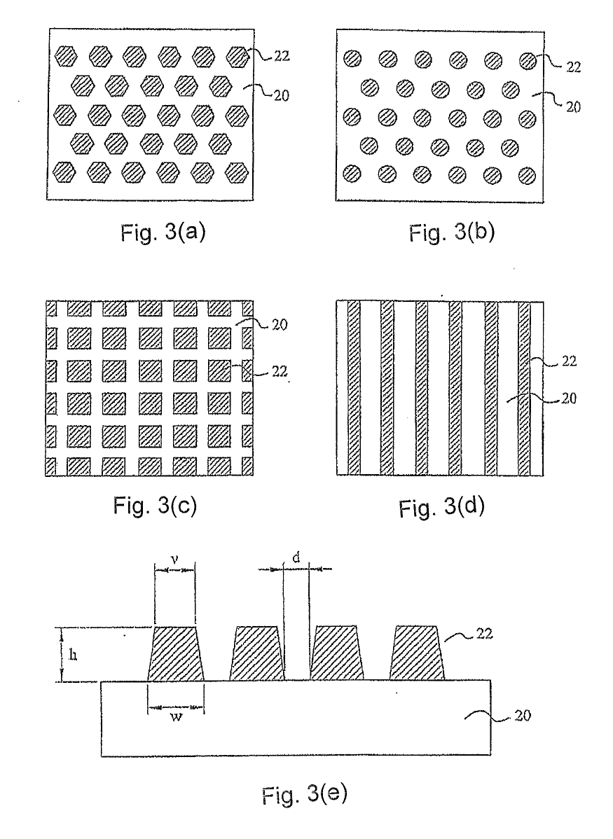

### DESCRIPTION OF THE PREFERRED EMBODIMENTS

Hereinafter, in order to make the effects of the present invention clear, embodiments are described with reference to the accompanying drawings.

### Embodiment 1

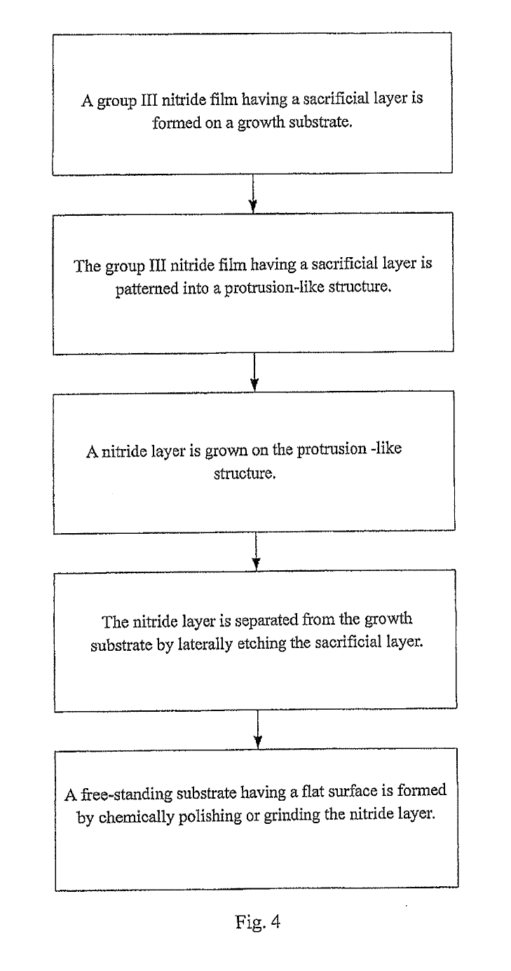

FIG. 4 is a flow chart explaining an embodiment of manufacturing a free-standing substrate of the present invention.

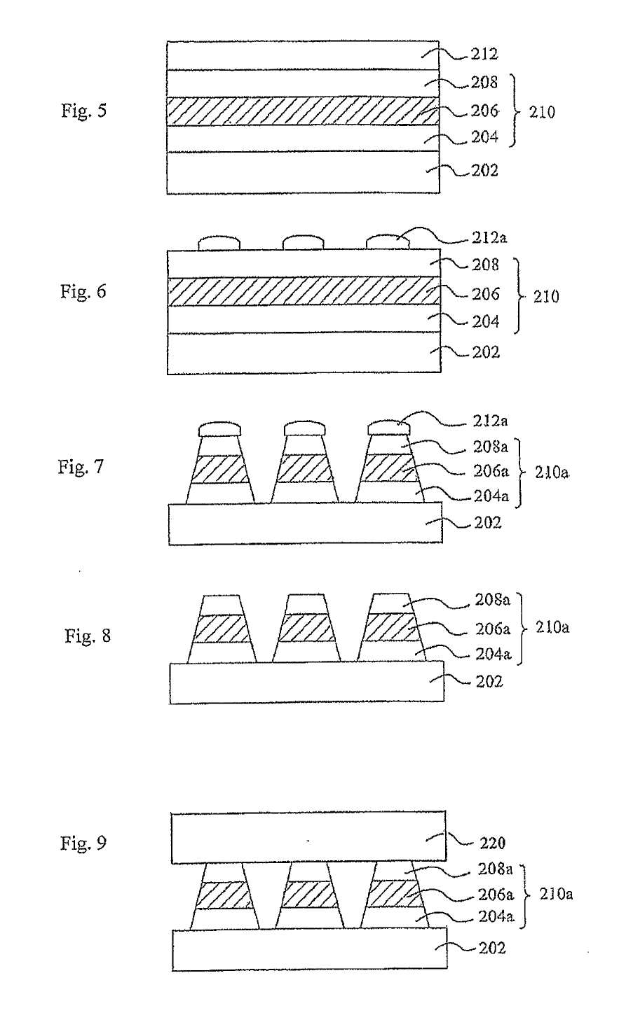

Referring to FIG. 5, a nitride film 204, an AlN film 206 (functioning as a sacrificial layer), and a nitride film 208 are sequentially grown on a sapphire substrate 202, and these three layers of films are defined as a first layer 210 having a sacrificial layer. A mask layer 212 is formed on the first layer.

Referring to FIG. 6, the mask layer 212 is patterned into a patterned mask layer 212a by photolithography.

Referring to FIG. 7, the first layer 210 is etched into a protrusion-like first layer 210a having a structure of a plurality of columns by using the patterned mask layer 212a as an etching mask, wherein the protrusion-like first layer 210a comprises a protrusion-like nitride layer 204a, a protrusion-like AlN film 206a, and a protrusion-like nitride layer 208a. Next, as shown in FIG. 8, the patterned mask layer 212a is removed.

Referring to FIG. 9, a nitride layer 220 is grown on the protrusion-like first layer 210a by epitaxial lateral overgrowth.

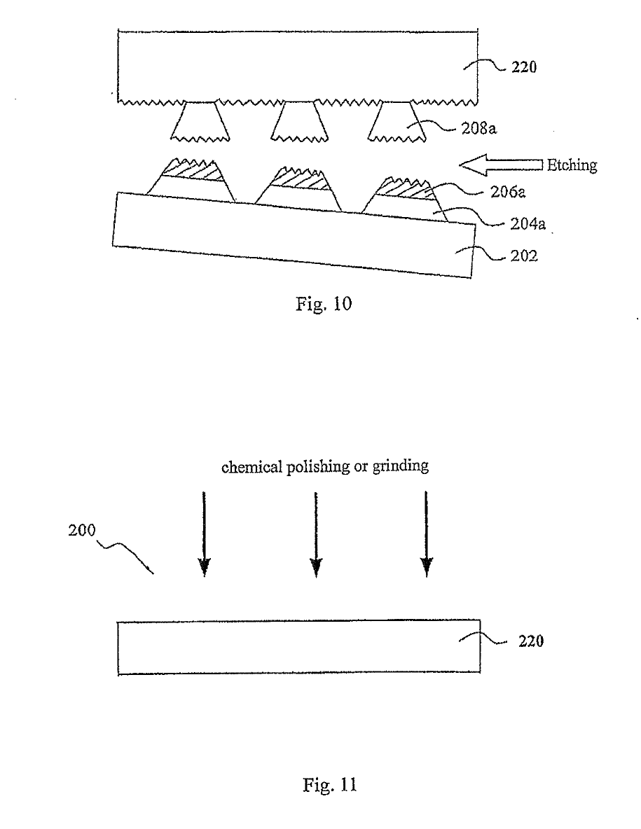

Referring to FIG. 10, AZ400K (a mixture solution of KOH and H₃BO₃ as main components, manufactured by Clariant Company) is used as an etchant to etch away the protrusion-like AlN film 206a, in order to separate the nitride layer 220 from the sapphire substrate 202. The nitride layer 220 is chemically polished or ground, thereby manufacturing a free-standing substrate 200 having a flat surface as shown in FIG. 11.

### Embodiment 2

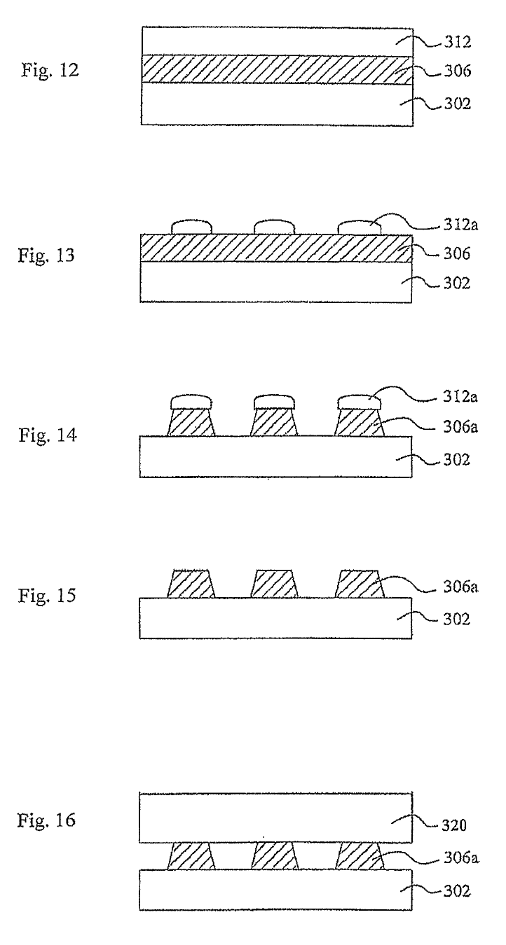

Referring to FIG. 12, an InₓAl_{y}Ga_{1-x-y}N film (0≦x≦1, 0≦y≦1, x+y≦1) functioning as a sacrificial layer 306 is grown on a sapphire substrate 302. A mask layer 312 is formed on the sacrificial layer 306.

Referring to FIG. 13, the mask layer 312 is patterned into a patterned mask layer 312a by photolithography.

Referring to FIG. 14, the sacrificial layer 306 is etched into a protrusion-like sacrificial layer 306a having a structure of a plurality of protrusions by using the patterned mask layer 312a as an etching mask. Then, as shown in FIG. 15, the patterned mask layer 312a is removed.

Referring to FIG. 16, a nitride layer 320 is grown on the protrusion-like sacrificial layer 306a by epitaxial lateral overgrown.

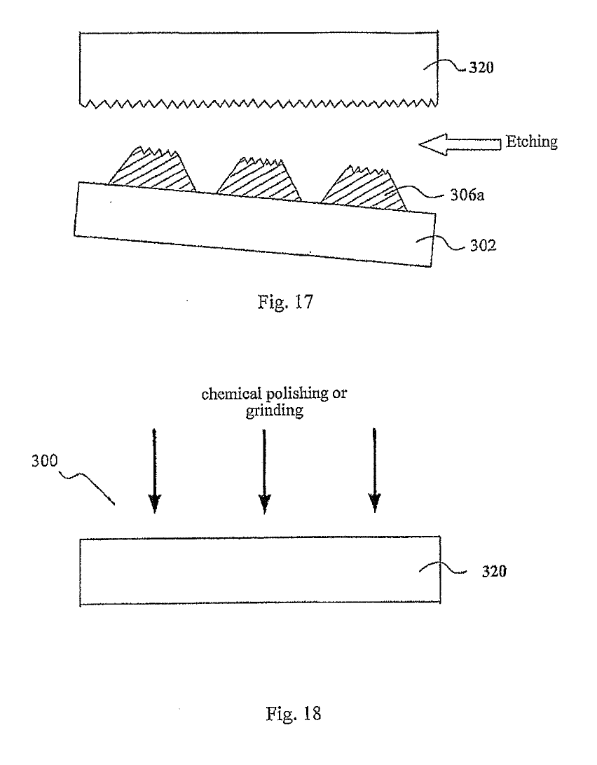

Referring to FIG. 17, AZ400K (a mixture solution of KOH and H₃BO₃ as main components, manufactured by Clariant Company) is used as an etchant to etch away the protrusion-like sacrificial layer 306a, in order to separate the nitride layer 320 from the sapphire substrate 302. The nitride layer 320 is chemically polished or ground, thereby manufacturing a free-standing substrate 300 having a flat surface as shown in FIG. 18.

### Embodiment 3

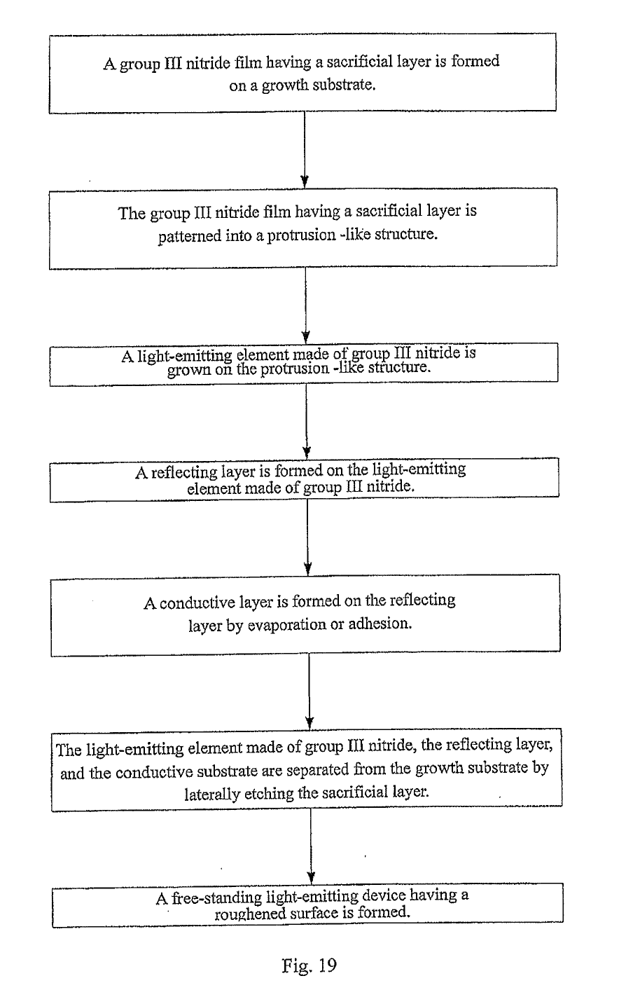

FIG. 19 is a flow chart explaining an embodiment of manufacturing a free-standing light-emitting device of the present invention.

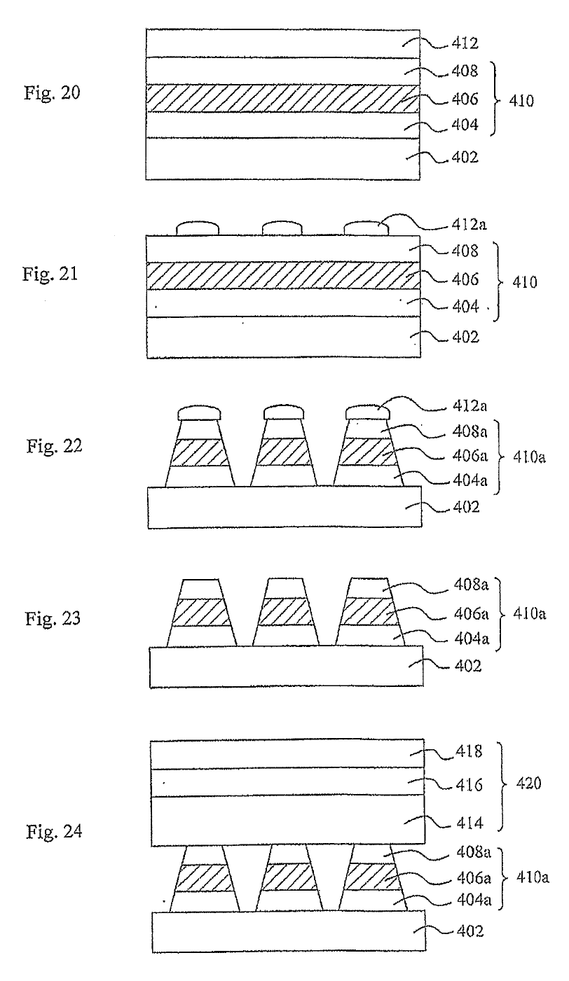

Referring to FIG. 20, a nitride film 404, an AlN film 406 (functioning as a sacrificial layer), and a nitride film 408 are sequentially grown on a sapphire substrate 402, and these three layers of films are defined as a first layer 410 having a sacrificial layer. A mask layer 412 is formed on the first layer.

Referring to FIG. 21, the mask layer 412 is patterned into a patterned mask layer 412a by photolithography.

Referring to FIG. 22, the first layer 410 is etched into a protrusion-like first layer 410a having a structure of a plurality of protrusions by using the patterned mask layer 412a as an etching mask, wherein the protrusion-like first layer 410a comprises a protrusion-like nitride layer 404a, a protrusion-like AlN film 406a, and a protrusion-like nitride layer 408a. Next, as shown in FIG. 23, the patterned mask layer 412a is removed.

Referring to FIG. 24, an n-type GaN film 414, a multiple quantum-well GaN film 416, and a p-type GaN film 418 for light emitting (these three layers of films are defined as a second layer 420) are sequentially grown on the protrusion-like first layer 410a by epitaxial growth.

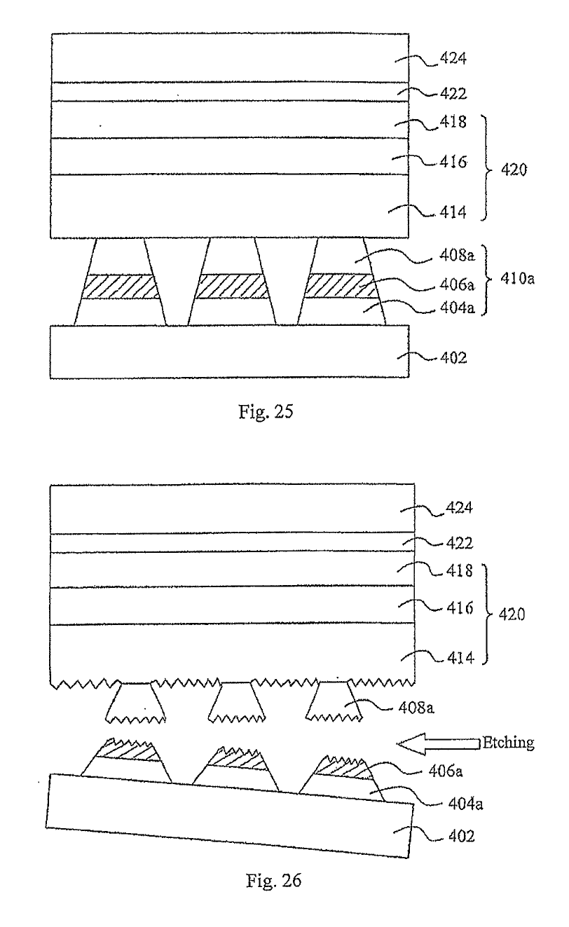

Referring to FIG. 25, a reflecting layer 422 is form on the second layer 420. Then, a conductive substrate 424 is adhered to the reflecting layer 422, alternatively, the conductive layer 424 is formed on the reflecting layer 422 by evaporation.

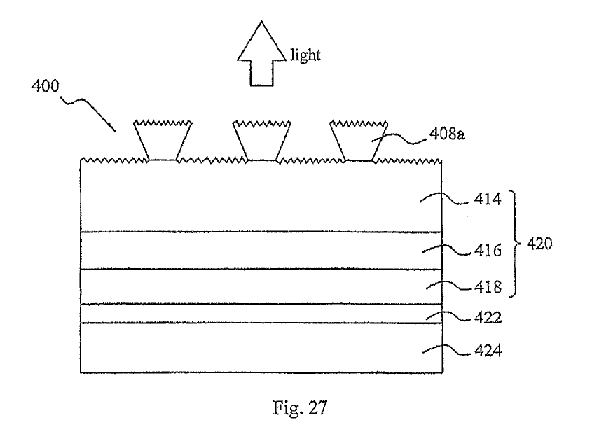

Referring to FIG. 26, AZ400K (a mixture solution of KOH and H₃BO₃ as main components, manufactured by Clariant Company) is used as an etchant to laterally etch away the protrusion-like AlN film 406a, in order to separate the second layer 420 (functioning as a light-emitting device 400), the reflecting layer 422, and the conductive layer 424 from the sapphire substrate 402. At the same time, the surfaces of the n-type GaN film 414 and the protrusion-like nitride film 408a are roughened, thereby manufacturing a free-standing vertical light-emitting device 400 having a roughened surface as shown in FIG. 27.

Although the present invention is described with reference to the embodiments, a person skilled in the art can easily make various changes and substitutions, without departing from the spirit and scope of the present invention as defined in the following claims.

### LIST OF REFERENCE NUMERALS

10 substrate
11 nitride layer
12 nanostructure (nano-columns)
14 p-GaN top layer
15 thick GaN
20 growth substrate
22 column
102 film of a first component
104 first substrate
108 bonding layer
110 second substrate
116 light
118 interfacial layer
200 free-standing substrate
202 sapphire substrate
204 nitride film
204a protrusion-like nitride film
206 AlN film (sacrificial layer)
206a protrusion-like AlN film
208 nitride film
208a protrusion-like nitride film
210 first layer
210a protrusion-like first layer
212 mask layer
212a patterned mask layer
220 nitride layer
300 free-standing substrate
302 sapphire substrate
306 sacrificial layer
306a protrusion-like sacrificial layer
312 mask layer
312a patterned mask layer
320 nitride layer
400 free-standing vertical light-emitting device
402 sapphire substrate
404 nitride film
404a protrusion-like nitride film
406 AlN film (sacrificial layer)
406a protrusion-like AlN film (sacrificial layer)
408 nitride film
408a protrusion-like nitride film
410 first layer
410a protrusion-like first layer
412 mask layer
412a patterned mask layer
414 n-type GaN film
416 multiple quantum-well GaN film
418 p-type GaN film
420 second layer
422 reflecting layer
424 conductive substrate
w bottom width of protrusion
v top width of protrusion
h height of protrusion
d distance between adjacent two protrusions

What is claimed is:

1. A method for manufacturing a free-standing substrate, comprising the steps of: growing a first layer having a sacrificial layer on a growth substrate; patterning the first layer into a patterned first layer having a structure of a plurality of protrusions; growing a second layer on the patterned first layer having a structure of a plurality of protrusions by epitaxial lateral overgrowth; and separating the second layer from the growth substrate by etching away the sacrificial layer, the separated second layer functioning as a free-standing substrate for epitaxy.

2. The method of claim 1, wherein the growth substrate is made of one selected from the group consisting of sapphire, silicon, silicon carbide, diamond, metal, LiAlO₂ (lithium aluminate, LAO), LiGaO₂ (lithium gallate, LGO), ZnO, GaAs, GaP, metal oxide, compound semiconductor, glass, quartz, and composite materials thereof.

3. The method of claim 1, wherein the first layer consists of a first group III nitride layer, a nitride sacrificial layer, and a second group III nitride layer, wherein the nitride sacrificial layer is between the first group III nitride layer and the second group III nitride layer, the first layer is 1 nm or more and 10 μm or less in thickness, the nitride sacrificial layer is 1 nm or more and 10 μm or less in thickness.

4. The method of claim 1, wherein the first layer consists of a group III nitride layer and a nitride sacrificial layer, wherein the nitride sacrificial layer is above or below the group III nitride layer, the first layer is 1 nm or more and 10 μm or less in thickness, the nitride sacrificial layer is 1 nm or more and 10 μm or less in thickness.

5. The method of claim 1, wherein the first layer consists of a nitride sacrificial layer, the first layer is 1 nm or more and 10 μm or less in thickness.

6. The method of any one of claims 3 to 5, wherein the nitride sacrificial layer is made of one selected from the group consisting of SiO₂, Si₃N₄, CrN, ZnO, TiN, Al₂O₃, (InₓAl_{y}Ga_{1-x-y}N), wherein 0≦x≦1, 0≦y≦1, x+y≦1, and combinations thereof.

7. The method of any one of claims 3 to 5, wherein the nitride sacrificial layer is a superlattice structure that comprises a plurality of alternating (InₓAl_{y}Ga_{1-x-y}N) sub-layer and (InₘAlₙGa₁₋ₘ₋ₙN) sub-layer, wherein 0≦m, n, x, y≦1, x+y≦1, m+n≦1, and m≠x, n≠y, 1-x-y≠1-m-n.

8. The method of claim 1, wherein the step of patterning the first layer comprises: forming a patterned mask layer on the first layer by photolithography process, lift-off process or imprint process and etching the first layer into a structure having a plurality of protrusions by using the patterned mask layer as an etching mask, alternatively, forming a plurality of masks on the first layer by spray or self-assembly and etching the first layer into a structure having a plurality of protrusions by the masks formed on the first layer.

9. The method of claim 1, wherein each protrusion on the growth substrate is in a pillar form or an elongated form, a bottom width w of each protrusion is 10 nm≦w≦1 mm, a top width v of each protrusion is 10 nm≦v≦1 mm, a height h of each protrusion is 1 nm≦h≦1 mm, and a distance d between two adjacent protrusions is 10 n≦d≦10 μm.

10. The method of claim 1, wherein the second layer is made of nitride.

11. The method of claim 1, wherein the etching is wet etching using an etchant which is one selected from the group consisting of AZ400K, KOH, H₃BO₃, H₂SO₄, H₃PO₄, HF, HNO₃, H₂O₂, HCl, buffered oxide etchant, and combinations thereof.

12. A method for manufacturing a free-standing light-emitting device, comprising the steps of: growing a first layer having a sacrificial layer on a growth substrate; patterning the first layer into a patterned first layer having a structure of a plurality of protrusions; growing a second layer on the patterned first layer having a structure of a plurality of protrusions by epitaxy growth; forming a reflecting layer on the second layer; forming a conductive substrate on the reflecting layer; and separating the second layer, the reflecting layer, and the conductive substrate from the growth substrate by etching away the sacrificial layer, so as to form a free-standing light-emitting device.

13. The method of claim 12, wherein the growth substrate is made of one selected from the group consisting of sapphire, silicon, silicon carbide, diamond, metal, LiAlO₂(lithium aluminate, LAO), LiGaO₂ (lithium gallate, LGO), ZnO, GaAs, GaP, metal oxide, compound semiconductor, glass, quartz, and composite materials thereof.

14. The method of claim 12, wherein the first layer consists of a first group III nitride layer, a nitride sacrificial layer, and a second group III nitride layer, wherein the nitride sacrificial layer is between the first group III nitride layer and the second group III nitride layer, the first layer is 1 nm or more and 10 μm or less in thickness, the nitride sacrificial layer is 1 nm or more and 10 μm or less in thickness.

15. The method of claim 12, wherein the first layer consists of a group III nitride layer and a nitride sacrificial layer, wherein the nitride sacrificial layer is above or below the group III nitride layer, the first layer is 1 nm or more and 10 μm or less in thickness, the nitride sacrificial layer is 1 nm or more and 10 μm or less in thickness.

16. The method of claim 12, wherein the first layer consists of a nitride sacrificial layer, the first layer is 1 nm or more and 10 μm or less in thickness.

17. The method of any one of claims 14 to 16, wherein the nitride sacrificial layer is made of one selected from the group consisting of SiO₂, Si₃N₄, CrN, ZnO, TiN, Al₂O₃, (InₓAl_{y}Ga_{1-x-y}N), wherein 0≦x≦1, 0≦y≦1, x+y≦1, and combinations thereof.

18. The method of any one of claims 14 to 16, wherein the nitride sacrificial layer is a superlattice structure that comprises a plurality of alternating (InₓAl_{y}Ga_{1-x-y}N) sub-layer and (InₘAlₙGa₁₋ₘ₋ₙN) sub-layer, wherein 0≦m, n, x, y≦1, x+y≦1, m+n≦1, and m≠x, n≠y, 1-x-y≠1-m-n.

19. The method of claim 12, wherein the step of patterning the first layer comprises forming a patterned mask layer on the first layer by photolithography process, lift-off process or imprint process and etching the first layer into a structure having a plurality of protrusions by using the patterned mask layer as an etching mask, alternatively, forming a plurality of masks on the first layer by spray or self-assembly and etching the first layer into a structure having a plurality of protrusions by the masks formed on the first layer.

20. The method of claim 12, wherein each protrusion on the growth substrate is in a pillar form or an elongated form, a bottom width w of each protrusion is 10 nm≦w≦1 mm, a top width v of each protrusion is 10 nm≦v≦1 mm, a height h of each protrusion is 1 nm≦h≦1 mm, and a distance d between two adjacent protrusions is 10 nm≦d≦10 μm.

21. The method of claim 12, wherein the second layer comprises: an n-type group III nitride layer, formed on the patterned first layer; a multiple quantum-well group III nitride layer, formed on the n-type group III nitride layer; and a p-type group III nitride layer, formed on the multiple quantum-well group III nitride layer.

22. The method of claim 12, wherein the etching is wet etching using an etchant which is one selected from the group consisting of AZ400K, KOH, H₃BO₃, H₂SO₄, H₃PO₄, HF, HNO₃, H₂O₂, HCl, buffered oxide etchant and combinations thereof.

23. The method of claim 12, wherein the reflecting layer is made of one selected from the group consisting of Ag, Al, Ni, Au, Pt, Ti, Cr, Pd, and alloys thereof.

24. The method of claim 12, wherein the conductive substrate is made of at least one selected from the group consisting of Cu, Si, Ni, Sn, Mo, AlN, SiC, SiCN, W, WC, CuW, TiW, TiC, GaN, diamond, metal, metal oxide, compound semiconductor, and composite materials thereof.
